(19) United States
(12) Patent Application Publication
(10) Pub. No.: US 2025/0309612 A1
(43) Pub. Date: Oct. 2, 2025

(54) HYBRID DISTRIBUTED REFLECTOR LASER

(71) Applicant: Junko Makino, Irvine, CA (US)

(72) Inventor: Toshihiko Makino, Irvine, CA (US)

(21) Appl. No.: 18/744,015

(22) Filed: Jun. 14, 2024

Related U.S. Application Data
(60) Provisional application No. 63/628,104, filed on Jun. 23, 2023.

(51) Int. Cl. H01S 5/042; H01S 5/00; H01S 5/10; H01S 5/125; H01S 5/34

(52) U.S. Cl. CPC H01S 5/0427; H01S 5/0064; H01S 5/1014; H01S 5/125; H01S 5/3412

(57) ABSTRACT

The invention provides a distributed reflector (DR) semiconductor laser, comprising a distributed feedback (DFB) laser and a distributed Bragg reflector (DBR).

### CROSS-REFERENCE TO RELATED APPLICATIONS

This application claims priority to and the benefit of U.S. Provisional Patent Application No. 63/628,104 filed on Jun. 23, 2023, the entirety of which is hereby incorporated by reference.

### BACKGROUND

### 1. Field

This invention relates to distributed reflector (DR) lasers for the optical transmitters in fiber optic network systems.

### 2. Description of the Related Art

Recent dramatic increase in the data capacity of the internet and related optical networks have required higher modulation speed of the optical transmitters. There have been three types of high-speed optical modulators: (1) directly modulated lasers (DML); (2) electro absorption (EA) modulators; and (3) Mach-Zehnder (MZ) modulators. The modulation bandwidths (BW) of the DMLs, the EA modulators, and the MZ modulators are limited to less than approximately 35 GHz, 60 GHz, and 30 GHz, respectively.

The DML has the advantages of small size, low cost, simple structure, low power consumption, and the capability of integrating with other photonic devices. The BW of the DML is limited fundamentally by the relaxation resonance frequency f_{R} (determined by the “electron-photon (E-P) resonance”). To increase the BW, higher f_{R} is required. A common approach for higher f_{R} is to use a short laser cavity length, described, for example, in the article by W. Kobayashi, T. Ito, T. Yamanaka, T. Fujisawa, Y. Shibata, T. Kurosaki, M. Kohtoku, T. Tadokoro, H. Sanjoh, “50-Gb/s direct modulation of a 1.3-μm InGaAlAs-based DFB laser with a ridge waveguide structure,” IEEE J. Sel. Topic Quantum Electronics, vol. 19, no. 4, no. 1500908, July/August 2013. This article shows that the f_{R} becomes maximum when the cavity length is reduced to 150 μm, and never exceeds approximately 26 GHz for further reducing the cavity length. Therefore, the f_{R} is limited fundamentally by the E-P resonance.

To break the E-P resonance limit, there have been mainly three approaches: (1) DBR laser; (2) DFB laser with an integrated passive waveguide; and (3) DR laser consisting of a DFB laser section and a DBR section.

The first approach is to use the so called “detuned loading” effect, in DBR lasers. This is described, for example, in the article by O. Kjebon, R. Schatz, S. Lourdudoss, S. Nilsson, B. Stalnacke, and L. Backbom, “Two-section InGaAsP DBR-lasers at 1.55 μm wavelength with 31 GHz direct modulation bandwidth,” in Conf. Proc. PRM, Hyannis, M A, May 1997, pp. 665-668, paper, ThF4. As shown in the article, in the DBR laser composing a uniform active section and a passive DBR section, the record high modulation bandwidth of 31 GHz was achieved. This is due to the increase of the effective differential gain, which is obtained by the lasing at a steep slope of the DBR reflection spectrum (detuned loading). For the dynamic behavior of DBR lasers, a theoretical model has been developed by U. Feiste, “Optimization of modulation bandwidth in DBR lasers with detuned Bragg reflectors”, IEEE J. Quantum Electronics, vol. 34, no. 12, pp. 2371-2379 December 1998. This model is a general multimode model based on the traveling-wave equations. Under the assumption of the rigid single-mode operation (only one mode considered), the enhanced E-P resonance frequency can be expressed analytically as

$${f}_{R} = {χ}_{R} {f}_{R , FP} \qquad ( 1 )$$

with

$${χ}_{R} = \sqrt{{L}_{a} Re ( \frac{1 + i {α}_{H}}{{L}_{a} + {L}_{eff}} )} \qquad ( 2 )$$

where f_{R,FP} is the relaxation resonance frequency of the FP laser without grating, Lₐ is the active region length, α_{H} is the linewidth enhancement factor (so called, the Henry's factor), L_{eff} is the effective length of a DBR, given as

$${L}_{eff} = \frac{1}{2} {iv}_{g} \frac{d ln {r}_{Reff}}{d ω} {\vert}_{ω = {ω}_{s}} \qquad ( 3 )$$

v_{g} is the group velocity, r_{Reff} is the amplitude reflectivity of the DBR, and ωₛ is the lasing angular frequency. We see from (1), (2), and (3) that f_{R} is affected by α_{H} and L_{eff}. It is shown by Feiste that if the second mode is added to the dominant mode, the modulation response can exhibit another resonance peak (so called photon-photon (P-P) resonance) at some modulation frequency much higher than the E-P resonance frequency. One example simulation shows the P-P resonance frequency of about 60 GHz, which corresponds roughly to the frequency separation between the dominant mode and the second mode.

The second approach is to use the P-P resonance effect in the passive feedback lasers (PFL), in which a passive waveguide is integrated with a DFB laser. This is described, for example, in the article by U. Troppenz, J. Kreissl, M. Mohrle, C. Bornholdt, W. Rehbein, B. Sartorius, I. Woods, M. Schell, “40 Gbit/s directly modulated lasers: physics and application,” Proc. SPIE vol. 7953, pp. 79530F1-F10, 2011. As is shown in the article, if the reflection feedback phase from the high reflection coated facet of the passive waveguide in the PFL laser, is properly chosen, a P-P resonance appears in the modulation response. Using this approach, the modulation bandwidth of 37 GHz was achieved. For the PFLs, numerical simulations based on the traveling-wave equations have been performed, which are described in the article, by M. Radziunas, A. Glitzky, U. Bandelow, M. Wolfrum, U. Troppenz, J. Kreissl, and W. Rehbein, “Improving the modulation bandwidth in semiconductor lasers by passive feedback,” IEEE J. Sel. Topic Quantum Electron, vol. 13, no. 1, pp. 136-142, January/February 2007: The simulated modulation response shows the P-P resonance in the range of 40˜60 GHz, depending on the feedback phase, in addition to the E-P resonance.

The third approach is to use both the detuned loading effect and the P-P resonance effect, in the DR lasers consisting of a DFB laser section and a DBR section. This is described, for example, in the article by Y. Matsui, R. Schatz, T. Pham, W. A. Ling, G. Carey, H. M. Daghighian, D. Adams, T. Sudo, and C. Roxlo, “50 GHz bandwidth distributed reflector laser,” J. Lightwave Technol., vol. 35, no. 3, pp. 397-403, Feb. 1, 2017. As is shown in the article, if the cavity lengths of the two sections and the grating coupling coefficients are properly chosen in the DR laser with a high reflection (HR) coating on the DFB laser facet, both the enhanced E-P resonance and the P-P resonance are obtained at the same time. The enhanced E-P resonance frequency of 30 GHz and the PP resonance frequency of 50 GHz were measured in the modulation response for the DR laser consisting of a DFB laser section of 50 μm and a DBR section of 200 μm. This achieved the modulation BW of 55 GHz. To provide a theoretical basis for the DR laser design, numerical simulations based on the transfer-matrix method together with multi-mode rate equations have been performed. The simulated modulation response shows both the enhanced E-P resonance at modulation frequency of 15˜40 GHz (which is a function of the injection current), and the P-P resonance at modulation frequency of around 60 GHz.

In the DR laser with high reflection (HR) coating on the DFB laser section facet (as described in the article cited above), the random variation of the grating phase at the facet may cause a variation of the P-P resonance frequency. To solve this problem, the DR laser structure composing of two DBRs, one of which plays a similar role to the HR coated facet, and two phase-shift regions for phase adjustment, is proposed in the U.S. Pat. No. 10,063,032 B2 (hereafter the “'032 patent”). The simulation assuming the phase-shift amount of 103° in the center of the DFB laser section shows a P-P resonance peak at modulation frequency of around 80 GHz.

### SUMMARY

It is an object of the present invention to provide a distributed reflector (DR) semiconductor laser, which are composed of a distributed feedback (DFB) laser section and a distributed Bragg reflector (DBR) section.

The modulation bandwidth can be increased further beyond the limit of that of the conventional DFB lasers. The cavity lengths and the grating coupling coefficients of the two sections are properly chosen, which provide, the so called, “photon-photon (P-P) resonance,” in addition to the conventional relaxation resonance (the electron-photon (E-P) resonance). The P-P resonance frequency is much higher than the E-P resonance frequency, due to the external optical feedback from the DBR section. The E-P resonance frequency itself can be increased due to the enhanced differential gain and the effective linewidth enhancement factor, if the lasing wavelength is chosen to be detuned from the peak of the DBR reflection spectrum (the detuned loading effect).

The DFB laser section may have a length (denoted by Lₐ) in a range from 100 micrometer (μm) to 200 μm. The DFB laser grating may have a product of the grating coupling coefficient κₐ and the length Lₐ, that is, κₐLₐ in a range from 2˜6. The DBR section may have a length (denoted by Lₚ) in a range from 200 μm to 400 μm. The DBR grating may have a product of the grating coupling coefficient κₚ and the length Lₚ, that is, κₚLₚ in a range from 2˜6. The anti-reflection (AR) coating on the DFB laser facet is provided, which can reduce the variation of the PP resonance frequency due to a random variation in the grating phase at the DFB laser facet. The DFB cavity length of larger than 100 μm can provide a high output power from the AR coated DFB laser facet.

According to another aspect of the present invention, the laser contact through which a modulation signal may be provided is formed to have a coplanar electrode structure. Due to the superior microwave transmission performance of the coplanar structure, the parasitic effect, and the propagation attenuation of the modulation signal at very high frequencies can be reduced, for even longer cavity length of the DFB section (>100 μm).

The present DR laser has three main features: (1) enhanced modulation bandwidth that is much larger than the limit of the conventional direct modulation; (2) superior microwave characteristics of the modulation signal on the contact electrode; and (3) performance optimization capability with a DBR separately built.

The first feature is provided by the so called “photon-photon (PP) resonance effect,” together with the so called “detuned loading effect.” The cavity lengths and the grating coupling coefficients of the two sections are chosen to exhibit the PP resonance, which is related to the optical feedback from the DBR section. The PP resonance frequency is much higher than the conventional relaxation (electron-photon (E-P)) resonance frequency. The lasing wavelength is chosen to be detuned from the peak of the DBR reflection spectrum (detuned loading), which results in the enhanced E-P resonance frequency due to the increase of the effective differential gain obtained on the slope of the DBR reflection spectrum. The second feature is provided by the coplanar electrode structure that can reduce the electric parasitic effects and the propagation attenuation of the modulation signal at very high frequencies. The third feature is provided by optically coupling the DFB laser chip of relatively long cavity length (>100 μm) to the DBR part that is formed on a silicon platform with increased design freedom.

### BRIEF DESCRIPTION OF THE DRAWINGS

Other systems, methods, features, and advantages of the present disclosure will be apparent to one skilled in the art upon examination of the following figures and detailed description. Component parts shown in the drawings are not necessarily to scale and may be exaggerated to better illustrate the important features of the present disclosure. In the drawings, like reference numerals designate like parts throughout the different views.

FIG. 1 is a cross-sectional view of a DR laser structure according to a first embodiment of the invention.

FIG. 2 is a perspective view of a DR laser structure according to a first embodiment of the invention.

FIG. 3A is a calculated normalized ASE spectra as a function of the wavelength.

FIG. 3B is a calculated normalized ASE spectra as a function of the optical frequency deviation from the Bragg frequency.

FIG. 4 is a calculated amplitude modulation response as a function of modulation frequency, which is normalized by the modulation response at zero modulation frequency for the laser structure of FIG. 1.

FIG. 5 is a calculated amplitude modulation response as a function of modulation frequency, which is normalized by the modulation response at zero modulation frequency for the laser structure of FIG. 1. The linewidth enhancement factor is taken as a parameter.

FIG. 6 is a perspective view of a coplanar DR laser structure according to a second embodiment of the invention.

FIG. 7 is a perspective view of a DR laser structure according to a third embodiment of the invention.

### DETAILED DESCRIPTION

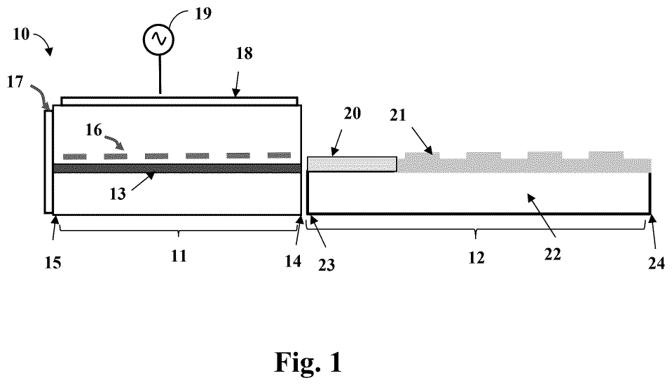

FIG. 1 illustrates a cross section of an example DR laser 10 according to a first embodiment of the present invention. The laser cavity comprises two sections, a DFB section 11 and a DBR section 12.

The DFB section 11 may include a gain region 13 that extends from the backside 14 to the front side 15 of the DFB section 11, having a length (denoted by Lₐ) in a range from 100 micrometer (μm) to 200 μm. The gain region 13 may include a multiple quantum well (MQW) region. In some embodiments, the quantum wells may be indium gallium arsenide phosphide (InGaAsP) materials or other suitable materials. A DFB grating 16 may have a product of the grating coupling coefficient κₐ and the length Lₐ, that is, κₐLₐ in a range of 2˜6. The DFB section 11 has a contact 18, and a modulation signal 19 may be provided to the contact 18. In examples, the DBR section 12 may be coupled end to end with the DFB section 11. The backside 14 of the DFB section 11 may be coupled the front side 23 of the DBR section 12. An anti-reflection (AR) coating 17 may be deposited on the front side 15 of the DFB section 11. In examples, the gain region 13 may comprise a multiple quantum well (MQW) or quantum dots structure. Other configuration may be utilized in examples.

The DBR section 12 is constructed with a spot size converter (SSC) 20, and a DBR grating 21 which are formed on a silicon platform 22 that extends from the front side 23 to the backside 24, having a length (denoted by Lₚ) in a range from 200 μm to 400 μm. The DBR grating 21 may have a product of the grating coupling coefficient κₚ and the length Lₚ, that is, κₚLₚ in a range from 2˜6. The DBR grating 21 is formed by etching a surface corrugation on the top surface of the silicon waveguide, as is demonstrated by H. Park et al., “Device and integration technology for silicon photonic transmitters,” IEEE J. Sel. Topics Quantum Electron., vol. 17, No. 3, pp. 671-688, May/June 2011. The SSC 20 is formed for making a smooth coupling of the output beam from the DFB section 11 to the DBR section 12. The DBR grating 21 may have a product of the grating coupling coefficient κₚ and the length Lₚ, that is, κₚLₚ in a range from 2˜6.

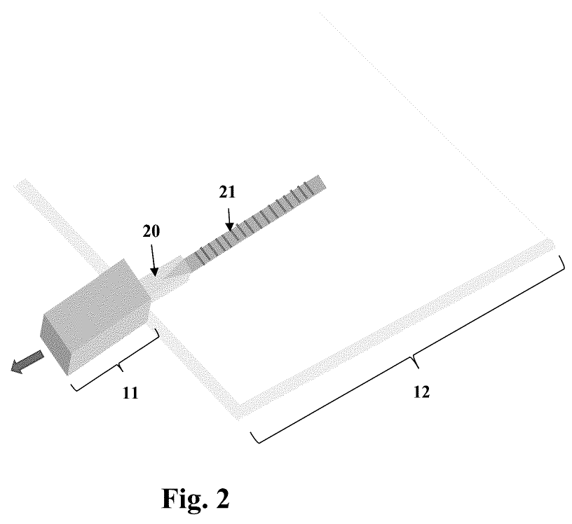

FIG. 2 is a perspective view to show the construction of the first embodiment of the DR laser 10 according to the present invention.

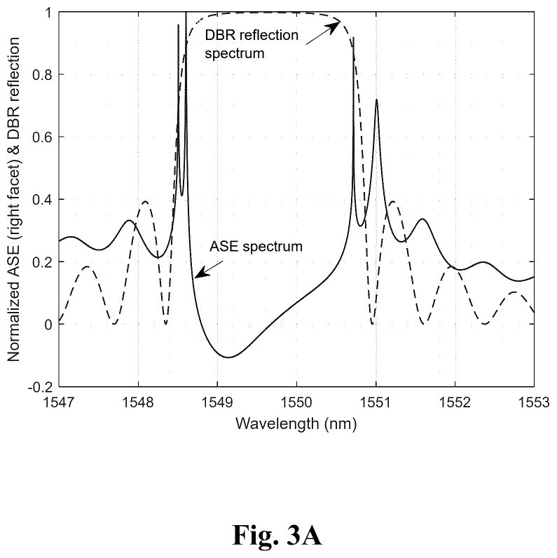

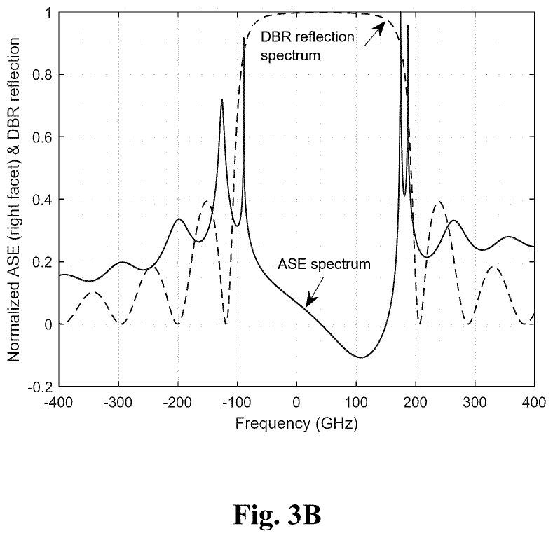

Principles of operation, for a DR laser according to the first embodiment, are described in the following. The static characteristics (threshold gain, lasing wavelength, and sub-threshold spectrum) of the DR laser can be analyzed by a general model, described in the article, by T. Makino, “Transfer-matrix formulation spontaneous emission noise of DFB semiconductor lasers,” J. Lightwave Technol., vol. 9, no. 1, pp. 84-91, January 1991. The power spectrum of amplified spontaneous emission (ASE) emitted from the laser facets can be simulated efficiently using a transfer matrix that represents each section of a general multisection laser. FIG. 3A shows calculated normalized ASE spectra as a function of the wavelength. FIG. 3B shows calculated normalized ASE spectra as a function of the optical frequency deviation from the Bragg frequency. The solid curve corresponds to the normalized ASE power spectral density emitted from the front facet of the DFB section below threshold for g/gₜₕ=0.99 where g and gₜₕ are the modal gain and its threshold value, respectively. The dashed curve corresponds to the DBR reflection spectrum (looking at the interface (see FIG. 1) towards the DBR in FIG. 1). In this calculation, Lₐ=190 μm, κLₐ=3.8, Lₚ=400 μm, κLₚ=3.7, and the linewidth enhancement factor (Henry factor), α_{H}=4, are assumed. The Bragg wavelengths of the DFB and DBR gratings (denoted by λ_{B-DFB} and λ_{B-DBR}, respectively) are assumed as λ_{B-DFB}=1550 nm and λ_{B-DBR}=1550 nm-0.35 nm. The main mode is obtained at around 1548 nm with threshold modal gain g₁=27 cm⁻¹, and the side mode is obtained at around 1551 nm with threshold modal gain g₂=32 cm⁻¹. To maintain the side mode suppression ratio (SMSR) of larger than 30 dB under modulation, the normalized threshold gain difference, (g₂−g₁)/g₁>0.1 is usually required. In this example, we have (g₂−g₁)/g₁=0.21, which meets the requirement. It is noted in FIG. 3A that two external cavity modes appear close to the DFB modes (see FIG. 3A), which are somehow related to the PP resonance.

The dynamic characteristics can be described by the rate equations for the envelope of the electric field and the carrier numbers in the total cavity. The small-signal AM and FM modulation characteristics and the AM and FM noise characteristics have been analyzed in the article by T. Makino, “Transfer-matrix theory of the modulation and noise of multielement semiconductor lasers,” IEEE J. Quantum Electron, vol. 29, no. 11, pp. 2762-2770 November 1993. If the modulation frequency becomes very high, the reflection feedback from the DBR section needs to be treated more accurately, since the phase of the DBR changes rapidly during the modulation. In this situation, the traveling-wave electric field needs to be used instead of the total electric field. The rate equation for the complex envelope function A⁺(t) of the forward (towards the DBR section) traveling-wave electric-field at the interface (represented in FIG. 1 as reference numbers 14 and 23) can be derived. This includes the complex envelope function A⁻(t) of the backward (towards the DFB section) traveling-wave electric-field, which can be expressed as

$${A}^{-} ( t ) = {\int }_{∞}^{∞} ρ ( {t}^{′} ) {A}^{+} ( t - {t}^{′} ) {dt}^{′} \qquad ( 4 )$$

with

$$ρ ( t ) = \frac{1}{2 π} {\int }_{- ∞}^{∞} {r}_{Reff} ( ω ) {e}^{j ( ω - {ω}_{s} ) t} d ω \qquad ( 5 )$$

where r_{Reff} is the effective reflection coefficient looking at the (represented in FIG. 1 as reference numbers 14 and 23) towards the DBR section, and @s is the stationary value of the lasing angular frequency. The rate equations for the amplitude and phase of the complex envelope function A⁺(t) can be derived. When the DFB laser is modulated with modulation angular frequency Ω, the optical angular frequency ω can be expressed as ω=ωₛ+Ω. Using this approach, the AM and FM noise of DFB lasers under external optical feedback from a simple (non-grating) reflector in distance has been analyzed, which is shown in the article by T. Makino, “Transfer-matrix analysis of the intensity and phase noise of multisection DFB semiconductor lasers,” IEEE J. Quantum Electron, vol. 27, no. 11, pp. 2404-2414 November 1991.

In the case of DR lasers, the reflector is a DBR, in which r_{R}_{_{eff}}(ω) is quite sensitive to Ω if ωₛ is located on the slope of the DBR grating spectrum (detuned loading), which makes ρ(t) quite sensitive to Ω. Applying this model, combining with the carrier rate equation, and assuming the small-signal modulation, we can analyze the modulation response in the frequency domain.

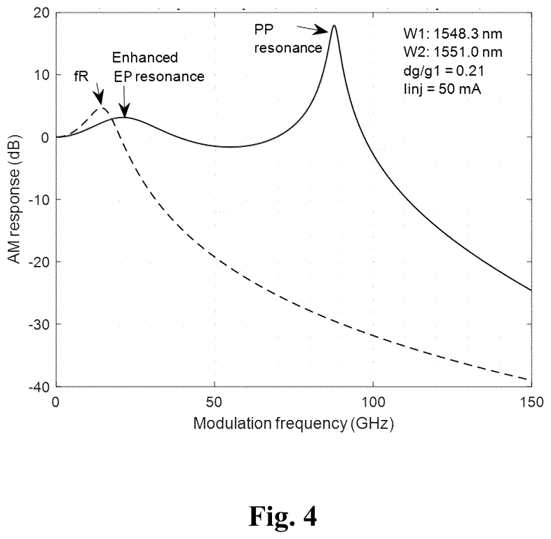

FIG. 4 shows a calculated amplitude modulation (AM) response as a function of the modulation frequency f=Ω/(2π). In this calculation, Lₐ=190 μm, κLₐ=3.8, Lₚ=400 μm, and κLₚ=3.7, and the linewidth enhancement factor, Δ_{H}=4, are assumed. The relaxation resonance frequency f_{R} for the solitary DFB laser without a DBR section is calculated to be about 16 GHZ (dashed curve in FIG. 4) for the normalized injection current I/Iₜₕ=1.8 where I is the injection current and Iₜₕ is the threshold current. In the assumed DR laser, two peaks appear in the AM response, one is the enhanced E-P resonance peak (at around 21 GHZ) and the other is the P-P resonance peak (at around 88 GHz).

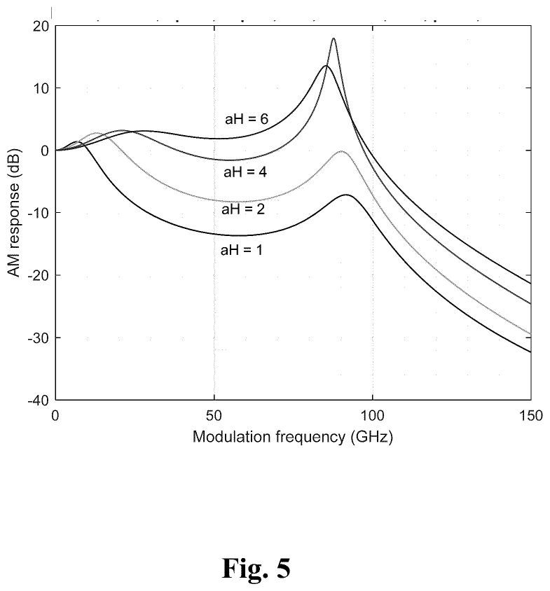

FIG. 5 shows the calculated AM responses for different values of the linewidth enhancement factor (α_{H}=1, 2, 4, and 6). As we see in FIG. 5, the enhanced E-P resonance frequency increases as α_{H} increases, due to the detuned loading effect. The P-P resonance frequency is not much affected by α_{H}, although the P-P resonance peak magnitude increases. Therefore, both the enhanced E-P resonance and the P-P resonance can be simulated self consistently.

The validity of the present model used for the simulations in FIGS. 4 and 5 will be explained by comparing to the results of the previous approaches cited above in the followings:

For the DBR laser in the article described by Feiste, in which Lₐ=100 μm, Lₚ=400 μm and κLₚ=1.6 with cleaved facet (31% power reflection) are assumed, the PP resonance frequency of ˜60 GHz is obtained for the detuning wavelength of 0.604 nm (lasing wavelength—DBR reflection peak wavelength). The present model gives the PP resonance frequency of 65˜70 GHz for λ_{B-DBR}=1549.5 nm˜1549.3 nm.

For the passive feedback lasers (PFL) in the article described by Radziunas et al., in which Lₐ=250 μm, κLₐ=3.3, Lₚ=300 μm, and α_{H}=4 are assumed, the PP resonance frequency of ˜31 GHz is obtained for injection current of 60 mA. The present model gives the PP resonance frequency of ˜31 GHz for injection current of 60 mA for the same laser parameters.

For the DR lasers in the article described by Matsui et al., in which Lₐ=50 μm, Lₚ=200 μm, and HR coating (93% power reflection) are used, the measured PP resonance frequency of ˜50 GHz is obtained for injection current of ˜35 mA. As is pointed out in the '032 patent, the simulated PP resonance frequency is shown to vary according to the grating phase, which is one problem for this approach. In the present model, for Lₐ=50 μm, κLₐ=0.7, Lₚ=250 μm, κLₚ=4.8, α_{H}=4, λ_{B-DBR}=1310.1 nm (λ_{B-DFB}=1310 nm), and injection current of 35 mA, the PP resonance frequency of ˜83 GHz is obtained when the grating phase at the HR (90% power reflection) coated facet is selected as 300°. It is observed that the PP resonance frequency varies according to the grating phase. Considering that there are some uncertainties in the laser parameters, this value is reasonable compared to the value ˜50 GHz in the article described by Matsui et al. above. The present model gives the enhanced EP resonance frequency of ˜20 GHz (the solitary laser has the EP resonance frequency of ˜13 GHZ).

Next, the advantages of the present model will be explained in the following. The traveling-wave models used in the cited articles are the multi-mode models, which require to solve the multimode rate equations numerically. Therefore, the insight of laser parameter interplays is difficult to obtain. In the present model, the rate equations for the amplitude and phase of the envelope electric field of the laser structure are solved under the small-signal assumption, which gives analytical expressions for the AM and FM modulation responses. The appearance of the PP resonance and the enhanced EP resonance can be related directly to the phase sensitive DBR parameters together with the DFB laser parameters. The ASE spectrum below threshold is calculated for the DR whole structure, and the lasing threshold is found by searching the zeros of the inverse of the ASE intensity peaks, which correspond to the threshold gain and the stationary lasing wavelength. Therefore, the PP resonance effect and the detuned loading effect can be related to the sub-threshold spectrum characteristics self consistently.

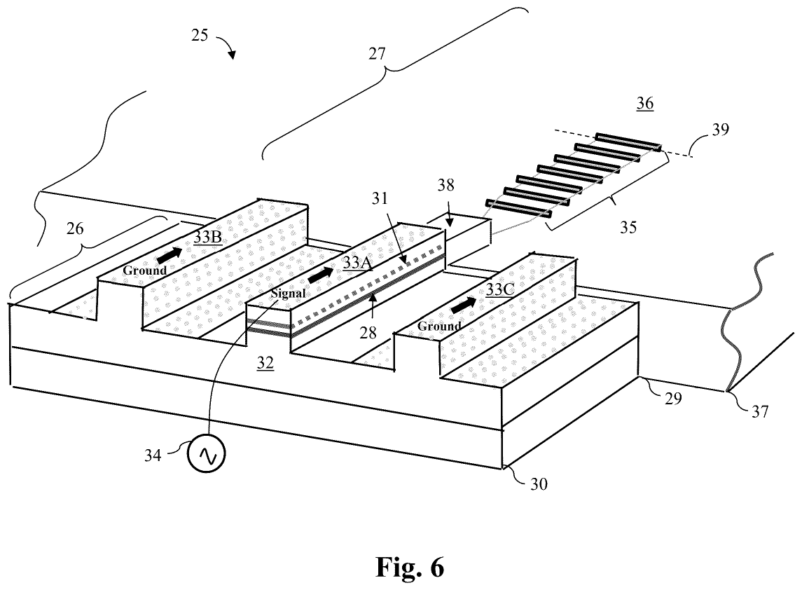

A second embodiment of a DR laser according to the present invention is described herein. FIG. 6 is a perspective view to show the construction of the second embodiment of a DR laser 25 according to the present invention. The schematic structure in FIG. 6 comprises a coplanar microwave transmission structure, which has superior performance at very high modulation frequencies.

For larger length of the DFB laser cavity, the propagation of the microwave signals along the laser stripe, may cause a significant increase in the microwave attenuation, as is described in the article by D. Tauber and J. Bowers, “Dynamics of wide bandwidth semiconductor lasers,” International Journal of High Speed Electronics and Systems, vol. 8, no. 3, pp. 377-416, 1997. The approach using the coplanar electrode for single section DFB lasers is demonstrated and described, for example, in the article by R-Y. Chen, Y-J. Chen, C-L. Chen, C-C. Wei, W. Lin, and Y-J. Chiu, “High-power long-waveguide 1300-nm directly modulated DFB laser for 45-Gb/s NRZ and 50-Gb/s PAM4,” IEEE Photon. Technol. Lett., vol. 30, no. 24, pp. 2091-2094 Dec. 15, 2018. The modulation BW of 26 GHz was achieved for the conventional DFB lasers with 250 μm cavity length. Although the microwave performance is improved by the coplanar electrode, the maximum BW is still limited by the E-P resonance frequency. Therefore, the present invention can break the E-P resonance limit by making the PP resonance with adding a DBR to the DFB laser section. In this embodiment of a DR laser 25, although a buried heterostructure (BH) type active region is used, a ridge waveguide structure can be used.

In FIG. 6, the laser cavity comprises two sections, a DFB section 26 and a DBR section 27. The DFB section 26 may include a gain region 28 that extends from the backside 29 to the front side 30, having a length (denoted by Lₐ) in a range from 100 micrometer (μm) to 200 μm. A DFB grating 31 may have a product of the grating coupling coefficient κₐ and the length Lₐ, that is, κₐLₐ in a range from 2˜6. An anti-reflection (AR) coating 32 (its physical thickness not shown in FIG. 6) is deposited on the front side 30. The contact electrode 33A is used for providing the modulation signal 34, and the other shaded metal electrodes 33B and 33C are used for the ground ports. The electrodes 33A, 33B, and 33C constitute a coplanar microwave transmission structure.

The DBR section 27 is constructed with a spot size converter (SSC) 38, and a DBR grating 35 which are formed on a silicon platform 36 that extends from a point after the spot size converter 38 to the backside 39, having a length (denoted by Lₚ) from the front side 37 in a range from 200 μm to 400 μm. The DBR grating 35 is formed by etching a surface corrugation on the top surface of the silicon waveguide. The DBR grating 35 may have a product of the grating coupling coefficient κₚ and the length Lₚ, that is, κₚLₚ in a range from 2˜6.

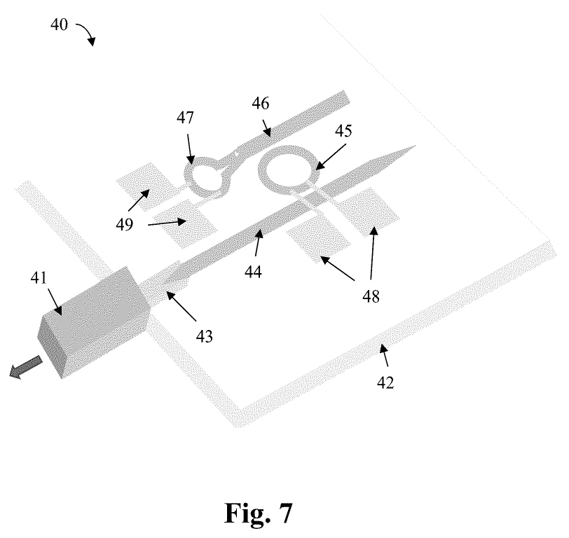

FIG. 7 is a perspective view to show the construction of a third embodiment of a DR laser 40 according to the present invention. A DFB laser chip 41 is optically coupled to a spot size converter (SSC) 43 formed on a silicon platform 42. The output of the SSC 43 is fed to a bus waveguide 44, which is coupled to a ring resonator 45, which is coupled to another bus waveguide 46. A loop mirror 47 is formed at the end of the bus waveguide 46. On the top of the ring resonator 45 and loop mirror 47, heaters are mounted to vary the refractive index of the silicon photonic waveguide by the thermos-optic effect. Electrodes 48 and 49 are put for supplying the bias to the ring resonator 45 and the loop mirror 47, respectively. The ring resonator 45 acts as a pass-band filter: The filter characteristics are determined by the ring radius, the waveguide width, and the coupling to the bus waveguides, as shown in the article described by B. E. Little, S. T. Chu, H. A. Haus, J. Foresi, and J.-P. Laine, “Microring resonator channel dropping filters,” J. Lightwave Technol., vol. 15, No. 6, pp. 998-15 Jun. 1997. The loop mirror 47 acts as a band reflector: The maximum reflection larger than 85% can be achieved for the ring resonator pass band, as shown in the article described by M. Ren, J. Pu, V. Krishnamurthy, L. Gonzaga, Y. T. Toh, F. Tjiptoharsono, Y. Yang, K. T. D. Ng, and Q. Wang, “A theoretical and experimental study of silicon Y-branch micro-loop reflectors”, IEEE Photon. Technol. Lett., vol. 28, pp. 2811-2814 December 2016. Therefore, the combination of the ring resonator 45 and the loop mirror 47 behaves like a DBR grating. Compared to the second embodiment in FIG. 6, the third embodiment has more design freedom for the DBR. The grating design of the DBR in FIG. 6 determines both the magnitude and phase characteristics simultaneously, while in FIG. 7, the ring resonator and the loop mirror can be designed independently. Therefore, the reflection magnitude and phase of the of the DBR can be optimized independently.

The present invention will be compared to the prior arts described in the Background of the Invention hereinafter. In the DBR laser approach, since the uniform active region is usually relatively long (100˜200 μm), several longitudinal modes exist within the DBR reflection band, which causes an ambiguity in the lasing wavelength accuracy. In the PFL approach, the passive waveguide has a HR coated facet, and its length is relatively long (˜200 μm). This creates a variation of the feedback phase, which in turn results in a variation of the P-P resonance frequency. In the DR laser approach, the approach of a short cavity DFB section with HR coating has a variation of the P-P resonance frequency due to the random variation of the grating phase at the HR facet. Although the approach of using two DBRs by replacing the HR by another DBR, is proposed, this requires the phase shift in the center of the DFB laser section. The phase control for the P-P resonance may require a very high precision control of cavity lengths and grating pitches, as well as complicated fabrication process.

Considering the descriptions above, the first advantage of the present invention is that the design and fabrication of the DBR may have more flexibility since silicon platform is used, and the performance optimization, especially the control of the PP resonance, may be greatly improved.

The second advantage of the present invention is that the cavity length of the DFB laser section can be larger than 100 μm, which is suitable for obtaining higher output power. For the DR lasers with DFB section length of 190 μm (which modulation response are shown in FIG. 3 and FIG. 4), calculated output powers from the DFB facet end and the DBR facet end are about 27 mW and 1 mW, respectively, for I/Iₜₕ=2.4 (where I and Iₜₕ are the injection current and its threshold current). The simulations were performed using the laser parameters which may represent the active layer comprising typical InGaAsP multiple quantum wells. Another aspect is that for handling a discrete DFB laser chip to couple to the separate DBR, the laser chip length larger than 100 μm is required.

The third advantage of the present invention is that the contact electrodes form a coplanar transmission line, which has superior microwave (to millimeter wave) performance at very high modulation frequencies for relatively longer cavity length of the DFB section.

In examples, the DR lasers disclosed herein may include a lasing mode at either a long wavelength side or a short wavelength side of a peak of a DBR reflection profile of the DBR section.

In examples, the DR lasers disclosed herein may have a photon-photon resonance frequency larger than 50 GHz.

Exemplary embodiments of the methods/systems have been disclosed in an illustrative style. Accordingly, the terminology employed throughout should be read in a non-limiting manner. Although minor modifications to the teachings herein will occur to those well versed in the art, it shall be understood that what is intended to be circumscribed within the scope of the patent warranted hereon are all such embodiments that reasonably fall within the scope of the advancement to the art hereby contributed, and that that scope shall not be restricted, except in light of the appended claims and their equivalents.

What is claimed is:

1. A distributed reflector (DR) laser, comprising:
a distributed feedback (DFB) section having a length in a range from 100 micrometers (μm) to 200 μm and comprising a DFB grating with a product of grating coupling coefficient kappa (κ) and a cavity length (L), κL, in a range from 2 to 6; and
a distributed Bragg reflector (DBR) section coupled end to end with the DFB section, having a length in a range from 200 μm to 400 μm, and comprising a DBR grating with a product of grating coupling coefficient kappa (κ) and a cavity length (L), κL, in a range from 2 to 6.

2. The DR laser of claim 1, wherein the DR laser comprises a coplanar electrode for applying a modulation signal.

3. The DR laser of claim 1, wherein the DFB section has a front side and a backside, the backside of the DFB section being coupled to the DBR section, the DR laser further comprising an anti-reflection (AR) coating formed on the front side of the DFB section.

4. The DR laser of claim 1, wherein the DFB section comprises a multiple quantum well (MQW) structure.

5. The DR laser of claim 1, wherein the DFB section comprises a quantum dots structure.

6. The DR laser of claim 1, further comprising a lasing mode at either a long wavelength side or a short wavelength side of a peak of a DBR reflection profile of the DBR section.

7. The DR laser of claim 6, wherein the DR laser has a photon-photon resonance frequency larger than 50 GHz.

8. The DR laser of claim 1, wherein the DBR section is formed on a silicon platform.

9. The DR laser of claim 1, further comprising a spot size converter (SSC) for making a smooth coupling of an output beam from the DFB section to the DBR section.

10. The DR laser of claim 1, further comprising a contact electrode for providing a modulation signal to the DFB section, and a plurality of other electrodes forming ground ports, the contact electrode and other electrodes comprising a coplanar microwave transmission structure.

11. A distributed reflector (DR) laser, comprising:
a distributed feedback (DFB) laser chip;
a spot size converter (SSC) optically coupled to the DFB laser chip;
a first bus waveguide for receiving an output of the SSC;
a ring resonator coupled to the first bus waveguide;
a second bus waveguide coupled to the ring resonator; and
a loop mirror coupled to the second bus waveguide.

12. The DR laser of claim 11, wherein the SSC is formed on a silicon platform.

13. The DR laser of claim 11, wherein the loop mirror is formed at an end of the second bus waveguide.

14. The DR laser of claim 11, wherein the ring resonator comprises a pass-band filter.

15. The DR laser of claim 11, further comprising electrodes for supplying bias to the ring resonator and the loop mirror.
